(19) United States
(12) Patent Application Publication
(10) Pub. No.: US 2021/0028126 A1
(43) Pub. Date: Jan. 28, 2021

(54) SUBSTRATE, DISPLAY PANEL, AND DISPLAY DEVICE

(71) Applicant: HKC CORPORATION LIMITED, Shenzhen (CN)

(72) Inventor: Huailiang HE, Shenzhen (CN)

(21) Appl. No.: 17/042,359

(22) PCT Filed: Dec. 19, 2018
(86) PCT No.: PCT/CN2018/122168

§ 371 Date: Sep. 28, 2020

(30) Foreign Application Priority Data
Dec. 4, 2018 (CN) 201811474243.3

(51) Int. Cl. H01L 23/00; G02F 1/1333; H01L 27/12

(52) U.S. Cl. CPC H01L 23/564; G02F 1/133308; G02F 1/133514; G02F 2201/56; H01L 27/1218

(57) ABSTRACT

A substrate, a display panel, and a display device are provided. The substrate includes: a substrate body; a hang buckle connecting member fixed at an edge of the substrate body and provided with a through hole.

### CROSS-REFERENCE TO RELATED APPLICATIONS

The present disclosure is the National Stage of International Application No. PCT/CN2018/122168, filed on Dec. 19, 2018, which claims the benefit of Chinese Patent Application No. 201811474243.3, filed on Dec. 4, 2018 and entitled “Substrate, Display Panel, and Display Device”, the entirety of which is incorporated herein by reference.

### FIELD

The present disclosure relates to the field of displays, and in particular, to a substrate, a display panel, and a display device.

### BACKGROUND

Wall-mounting displays such as televisions, monitors, displays used in public, etc., have become increasingly common due to the advantage of saving space.

Currently, the wall-mounting displays are mounted to the wall by using brackets, so the displays cannot closely attach to the wall.

The statements herein merely provide background information related to the present disclosure and do not necessarily constitute prior art.

### SUMMARY

The main purpose of the present disclosure is to provide a substrate, by which the distance between a wall-mounting display device and a wall may be reduced when the substrate is applied in the wall-mounting display device.

In order to achieve the above purpose, the present disclosure provides a substrate, which is applied to a display device. In an embodiment of the present disclosure, the substrate includes:

a substrate body; and

a hang buckle connecting member fixed at an edge of the substrate body and provided with a through hole.

In an embodiment of the present disclosure, the hang buckle connecting member is fixed at a top and/or a lateral side of the substrate body.

In an embodiment of the present disclosure, the hang buckle connecting member has a rectangular shape.

In an embodiment of the present disclosure, the hang buckle connecting member has a rectangular shape, and the through hole is a rectangular hole.

In an embodiment of the present disclosure, the hang buckle connecting member is integrally formed with the substrate body.

In an embodiment of the present disclosure, the substrate is a color film substrate or an array substrate.

The present disclosure further provides a display panel. The display panel includes a substrate, and the substrate includes a substrate body, and a hang buckle connecting member fixed at an edge of the substrate body and provided with a through hole.

In an embodiment of the present disclosure, the hang buckle connecting member is fixed at a top and/or a lateral side of the substrate body.

In an embodiment of the present disclosure, the hang buckle connecting member is a rectangular hole.

In an embodiment of the present disclosure, the hang buckle connecting member has a rectangular shape, and the through hole is a rectangular hole.

In an embodiment of the present disclosure, the hang buckle connecting member is integrally formed with the substrate body.

In an embodiment of the present disclosure, the substrate is a color film substrate or an array substrate.

In an embodiment of the present disclosure, the substrate is a color film substrate.

The display panel further includes:

an array substrate disposed opposite to the color film substrate; and

a liquid crystal layer disposed between the array substrate and the substrate body of the color film substrate.

In an embodiment of the present disclosure, the substrate is an array substrate.

The display panel further includes:

a color film substrate disposed opposite to the array substrate; and

a liquid crystal layer disposed between the color film substrate and the substrate body of the array substrate.

The present disclosure further provides a display device. The display device includes a display panel including a substrate. The substrate includes a substrate body, and a hang buckle connecting member fixed at an edge of the substrate body and provided with a through hole.

In an embodiment of the present disclosure, the hang buckle connecting member is fixed at a top and/or a lateral side of the substrate body.

In an embodiment of the present disclosure, the hang buckle connecting member has a rectangular shape.

In an embodiment of the present disclosure, the hang buckle connecting member has a rectangular shape, and the through hole is a rectangular hole.

In an embodiment of the present disclosure, the hang buckle connecting member is integrally formed with the substrate body.

In an embodiment of the present disclosure, the display device further includes a casing, and the display panel is mounted on the casing, and the hang buckle connecting member protrudes from the casing.

According to the technical solution of the present disclosure, the substrate includes the substrate body and the hang buckle connecting member fixed at the edge of the substrate body and provided with the through hole. When the substrate is applied to a display device, it is no longer necessary to provide a corresponding structure on the display device for the display device to be wall-mounted. A hang buckle is provided on the wall to be tightly buckled with the hang buckle connecting member by the through hole, so as to provide support to the display device, thereby wall-mounting of the display device is achieved. Moreover, since the hang buckle connecting member is fixed at the edge of the substrate body, a back surface of the display device is able to completely attach to the wall, thereby reducing a gap between the display device and the wall.

### BRIEF DESCRIPTION OF THE DRAWINGS

In order to more clearly illustrate the technical solutions in the embodiments of the present disclosure or the exemplary techniques, the drawings to be used in the embodiments or the description of the exemplary embodiments will be briefly described below. Obviously, the drawings in the following description are only certain embodiments of the present disclosure, and other drawings may be obtained according to the structures shown in the drawings without any creative work for those skilled in the art.

FIG. 1 is a schematic structural diagram of a display panel according to an embodiment of the present disclosure.

FIG. 2 is a schematic structural diagram of a display device according to an embodiment of the present disclosure.

FIG. 3 is a schematic diagram showing a wall-mounted state of a display device according to an embodiment of the present disclosure.

The implementation, functional features and advantages of the present disclosure will be further described with reference to the accompanying drawings.

### DETAILED DESCRIPTION OF THE EMBODIMENTS

The technical solutions in the embodiments of the present disclosure are clearly and completely described in the following with reference to the drawings in the embodiments of the present disclosure. It is obvious that the described embodiments are only a part of the embodiments of the present disclosure, and not all of the embodiments. All other embodiments obtained by those of ordinary skill in the art without creative labor based on the embodiments here are within the scope of protection in the present disclosure.

It should be noted that all directional indications (such as up, down, left, right, front, back, . . . ) in the embodiments of the present disclosure are only used to explain relative positional relationship, motion situation, etc. between components in a certain posture (as shown in the drawing). If the specific posture changes, the directional indication also changes accordingly.

In the present disclosure, the terms “connected”, “fixed” and the like should be understood broadly, unless otherwise explicitly stated and defined. For example, “fixed” may be a fixed connection, or may be a detachable connection, or may be integrated; it may be a mechanical connection or an electrical connection; it may be directly connected or indirectly connected through an intermediate medium, and may be an internal connection of two elements or an interaction relationship of two elements unless explicitly defined otherwise. For those skilled in the art, the specific meanings of the above terms in the present disclosure can be understood on a case-by-case basis.

In addition, the descriptions of “first”, “second”, and the like in the present disclosure are used for the purpose of description only, and are not to be construed as indicating or implying their relative importance or implicitly indicating the number of technical features indicated. Thus, features defining “first” or “second” may include at least one of the features, either explicitly or implicitly. In addition, the technical solutions between the various embodiments may be combined with each other, but must be based on the realization of those skilled in the art, and when the combination of the technical solutions is contradictory or impossible to implement, it should be considered that the combination of the technical solutions does not exist, nor is it within the scope of protection required by this disclosure.

Currently, display devices such as televisions, monitors, etc. are usually seated by a base or wall-mounted by a wall-mounted bracket.

When the display device is seated and fixed, it needs to be combined with the base, and then be placed on the support platform. For example, when a television is seated and fixed, it needs to be installed with a base, and then be placed on the TV cabinet. In this case, although the support of the television is realized, the installation of the TV cabinet occupies a large space and the cost is higher.

When the display device is wall-mounted by the wall-mounted bracket, a back of the display device needs to be combined with the wall-mounted bracket, and the wall-mounted bracket needs to be fixed on the wall. For example, when the television is wall-mounted, a back of the television is fixed with the wall-mounted bracket. In this case, although the support of the television is realized, the wall-mounted bracket needs to be accommodated between the television and the wall, so the television cannot attached to the wall, and the television still protrudes from the wall to a large extent.

Therefore, in order to reduce the distance between a display device 1 and the wall when the display device 1 is wall-mounted, the main solution of the present disclosure is: a substrate 100 includes a substrate body 110 and a hang buckle connecting member 120, and the hang buckle connecting member 120 is fixed at an edge of the substrate body 110, and the hang buckle connecting member 120 is provided with a through hole 121. The substrate 100 of the present disclosure includes a substrate body 110 and a hang buckle connecting member 120, and the hang buckle connecting member 120 is fixed at an edge of the substrate body 110, and the hang buckle connecting member 120 is provided with a through hole 121. When the substrate 100 is provided as the display device 1, it is no longer necessary to provide a corresponding structure on the display device 1 for the display device 1 to be wall-mounted. A hang buckle 400 is provided on the wall to be tightly buckled with the hang buckle connecting member 120 by the through hole 121, so as to provide support to the display device 1, thereby wall-mounting of the display device 1 is achieved. Moreover, since the hang buckle connecting member 120 is fixed at the edge of the substrate body 110, a back surface of the display device 1 is able to completely attached to the wall, thereby reducing a gap between the display device 1 and the wall.

Based on the above problems, the present disclosure provides the substrate 100, which is provided as the display device 1.

In an embodiment of the present disclosure, as shown in FIG. 1 to FIG. 3, the substrate 100 includes:

the substrate body 110; and

the hang buckle connecting member 120 fixed at the edge of the substrate body 110 and provided with the through hole 121.

The display device 1 is a device for outputting information, which is also called a display, which can convert the data of the computer into various characters, numbers, symbols or images, and can add, modify, change the display content and display at any time by means of a computer. The device 1 may be classified into a liquid crystal display, an organic light emitting diode (OLED) display, etc. according to the different principle.

A substrate is required for both the display panel portion of the liquid crystal display and the OLED display. For example, in the liquid crystal display, a display panel of the liquid crystal display is composed of an array substrate and a color film substrate, and a liquid crystal is filled between the array substrate and the color film substrate. The array substrate and the color film substrate are one kind of the substrates, respectively, and materials of the two may be the same (for example, may be a glass substrate), and structures formed on the two are different. For another example, the OLED display has the array substrate on which an organic self-luminous layer is disposed. Namely, the substrate is an important component of the display panel in the display device. The display panel is prepared from the substrate, and is mounted together with a backlight in the casing to form the display device.

In this embodiment, referring to FIG. 1, the substrate 100 includes the substrate body 110 and the hang buckle connecting member 120. Generally, the substrate body 110 includes a display area and a non-display area located at a periphery of the display area. The display area is an area where content can be displayed, and the non-display area is an area where content is not displayed. For example, for the array substrate of the liquid crystal panel, the display area of the array substrate is mainly provided with a thin film transistor (TFT), a pixel electrode, a storage capacitor, etc., and the non-display area of the array substrate is mainly provided with a fan-out trace. For another example, for the color film substrate of the liquid crystal panel, the display area of the color film substrate is mainly provided with a black matrix, a color filter film, etc., and color filters of each color on the color film substrate corresponds to unit pixels on the array substrate one by one. Namely, the edge of the substrate body 110 that the hang buckle connecting member 120 is fixed at is at the non-display area of the substrate body 110, so the display effect of the display panel 2 is not affected after being prepared from the substrate 110.

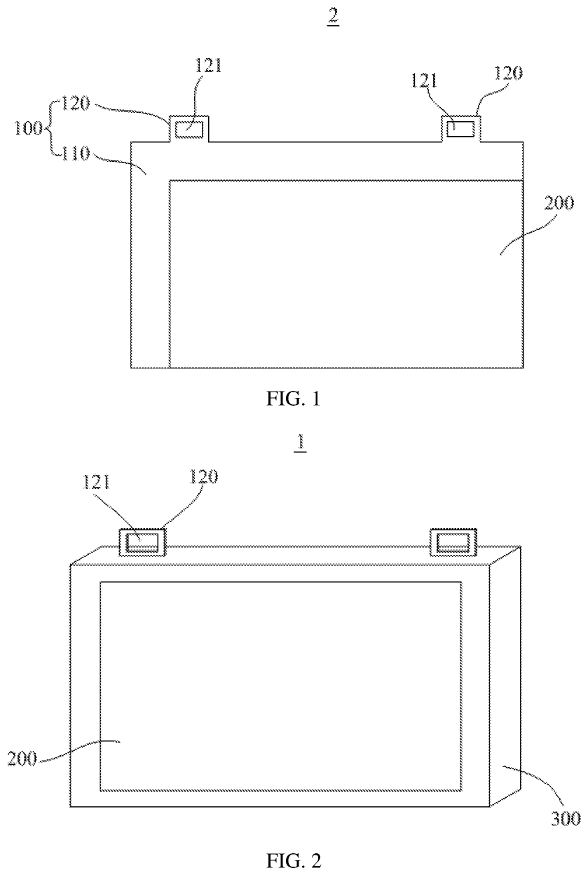

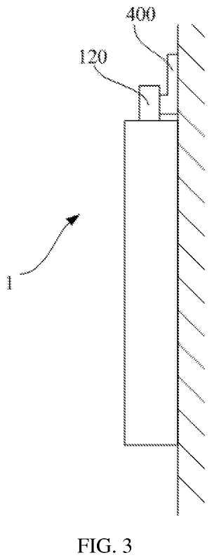

The hang buckle connecting member 120 is fixed at the edge of the substrate body 110, so the whole substrate 100 is fixed by fixing the hang buckle connecting member 120, and the display device 1 prepared from the substrate 100 is wall-mounted as well. Specifically, referring to FIG. 2 and FIG. 3, the display panel 2 is prepared from the substrate 100, and the display panel 2 and the backlight are assembled together into a casing 300. The hang buckle connecting member 120 protrudes from the casing 300 through the wall. A hang buckle 400 is provided on the wall to be tightly buckled with the hang buckle connecting member 120 by the through hole 121, namely the hang buckle connecting member 120 is fixed at the hang buckle 400, thereby wall-mounting of the display device 1 is achieved. Since the display device 1 is wall-mounted by the hang buckle connecting member 120, the corresponding structure provided for the wall-mounting is no longer needed on the display device 1, nor as the wall-mounted bracket between the display device 1 and the wall. The display device 1 is able to completely attached to the wall, thereby the gap between the display device 1 and the wall is reduced. Since the display device 1 is wall-mounted by the substrate 100, the casing 300 of the display device may be further lightened, so that the weight of the entire display device 1 may be reduced.

In an embodiment of the present disclosure, as shown in FIG. 1 to FIG. 3, the hang buckle connecting member 120 is fixed at a top of the substrate body 110. In this embodiment, when the display device 1 is prepared from the substrate 100 and is wall-mounted, it tends to fall downward under the action of gravity. Thus in this embodiment, the hang buckle connecting member 120 is fixed at the top of the substrate body 110 and protrudes from the top of the display device 1. When the hang buckle connecting member 120 is buckled to the hang buckle 400, the entire display device 1 is lifted and has a tendency to rotate downward around a connection point with the hang buckle 400, so that the display device 1 is more closely attached to the wall, and the wall also provides support for the display device 1, thereby making the entire display device 1 more stable.

In an embodiment of the present disclosure, the hang buckle connecting member 120 is fixed at lateral side of the substrate body 110. In this embodiment, the display device 1 has a rectangular shape, namely, of which a length is greater than a width to achieve a better visual effect, such as some 16:9 televisions. Since the display device 1 has a long length, the support device 1 is supported from both sides by fixing the hang buckle connecting member 120 on the sides of the substrate body 110, thereby a swing of the wall-mounted display device 1 due to insufficient support is avoided.

In an embodiment of the present disclosure, the hang buckle connecting member 120 is fixed at the top and the lateral side of the substrate body 110. In this embodiment, the hang buckle connecting member 120 is fixed at the top and the lateral side of the substrate body 110. Therefore, the display device 1 prepared from the substrate 100 of the present embodiment has effects of both the display device 1 of which the hang buckle connecting member 120 fixed at the top of the substrate body 110, or the display device 1 of which the hang buckle connecting member 120 fixed at the lateral side of the substrate body 110, which will not be repeated here. Further, the display device 1 is fixed in a horizontal direction and a longitudinal direction by fixing the hang buckle connecting member 120 to the top and the lateral side of the substrate body 110, thereby the wall-mounted display device 1 is more stable.

The hang buckle connecting member 120 is not limited to one, and may have various shapes such as a semicircle, or a triangle. In order to further improve a cutting efficiency of the substrate 100, in an embodiment of the present disclosure, as shown in FIG. 1, the hang buckle connecting member 120 has a rectangular shape. The substrate 100 of each display device is cut by a single substrate. Therefore, in this embodiment, the hang buckle connecting member 120 is in a rectangular shape to improve the cutting efficiency when cutting a whole substrate.

In an embodiment of the present disclosure, as shown in FIG. 1 and FIG. 2, the hang buckle connecting member 120 has a rectangular shape, and the through hole 121 is a rectangular hole. Similar to the previous embodiment, the hang buckle connecting member 120 in this embodiment has a rectangular shape to facilitate improving cutting efficiency when cutting a single substrate. The through hole 121 of the present embodiment is a rectangular hole, and the cutting efficiency may also be improved when cutting. Certainly, in another embodiment of the present disclosure, the through hole may also have a circular shape or an elliptical shape etc.

Further, in order to ensure that the substrate 100 is not easily broken when the display device 1 is suspended, the through hole 121 is defined at an intermediate position of the hang buckle connecting member 120, and distances between edges of the through hole 121 and the edges of the hang buckle connecting member 120 are the same. In this embodiment, the hang buckle connecting member 120 is fastened to the wall, so that the display device 1 is wall-mounted. Therefore, the substrate 100 carries the overall weight of the display device 1. The through hole 121 is defined at an intermediate position of the hang buckle connecting member 120, and distances between edges of the through hole 121 and the edges of the hang buckle connecting member 120 are the same, making the force on the hang buckle connecting member 120 be more evenly balanced to prevent local cracking.

In an embodiment of the present disclosure, the hang buckle connecting member 120 is integrally formed with the substrate body 110. In this embodiment, the substrate 100 is a glass substrate. The hang buckle connecting member 120 is integrally formed with the substrate body 110, namely, a single large-sized substrate is prepared, then the substrate 100 in this embodiment is obtained by cutting the large-sized substrate. The cut substrate 100 includes the substrate body 110 and the hang buckle connecting member 120, thus the substrate body 110 and the hang buckle connecting member 120 are considered to be integrally formed.

Two preparation methods for the glass substrate are given below:

Float glass manufacturing method: the molten glass paste which has been initially cooled floats through a flat molten Tin bed filled with reducing gas. The viscosity of the glass paste is low, so the thickness of the glass may be controlled by a baffle or a tie rod. During the process of floating through the liquefied Tin bed, the glass paste is gradually solidified into a glass plate, then the solidified glass plate is taken out by a guide wheel and annealed. The size of the glass substrate produced by this method may be made large and the yield is also high.

Overflow melting manufacturing method: a low-viscosity homogeneous glass paste is led into a flow hole drain plate groove made of a platinum alloy, and the thickness of the glass is controlled by gravity, the pull-down force, and the size of the die opening. The temperature and the size of the flow hole determine the yield of the glass substrate, and the size of the flow hole and the lead speed determine the thickness of the glass substrate, and the temperature distribution determines the warpage of the glass substrate. The glass substrate manufactured by this method has no surface damage caused by the float glass manufacturing method.

The single large-sized glass substrate is prepared, and the substrate 100 provided as the display device 1 is formed by it.

In an embodiment of the present disclosure, the substrate 100 is a color film substrate or an array substrate.

In this embodiment, the array substrate is provided with a thin film transistor, a signal line, a pixel electrode, a storage capacitor, and a peripheral protection circuit. Specifically, the array substrate is provided with a plurality of pixels, each of which includes a switching device thin film transistor, a storage capacitor, and a pixel electrode. The gate of the thin film transistor is connected to a scan line, and a source of the thin film transistor is connected to a data line, and a drain electrode is connected to the pixel electrode.

The color film substrate is provided with a black matrix, a color filter film, an overcoat, and an transparent conductive film Indium Tin Oxide (ITO semiconductor transparent conductive film). The color filter film may be a color filter film of three primary colors of red, green and blue, and filter films for each type of diffraction on the color film substrate correspond with unit pixels on the array substrate one by one.

In the liquid crystal display device, the display panel of the liquid crystal display device includes the color film substrate and the array substrate, and the color film substrate and/or the array substrate adopts the structure of the substrate 100 in the above embodiments, so that no wall-mount bracket is needed between the wall-mounted liquid crystal display device and the wall, making the liquid crystal display device attach to the wall more.

The present disclosure further provides a display panel 2.

In an embodiment of the present disclosure, the display panel 2 includes the substrate 100 in any of the above embodiments.

In this embodiment, the display panel 2 includes a liquid crystal display panel, an OLED panel, etc. The specific structure of the substrate 100 of this embodiment is referred to the above embodiments. Since the substrate 100 of the display panel 2 of this embodiment adopts the technical solutions of the above embodiments, it has at least the effects of the technical solutions of the above embodiments and will not be repeated here.

The structure of the substrate 100 refers to the structure of the substrate of the above embodiment: the substrate 100 includes the substrate body 110 and the hang buckle connecting member 120. The hang buckle connecting member 120 is fixed at the edge of the substrate body 110, and the hang buckle connecting member 120 is provided with the through hole 121.

In an embodiment of the present disclosure, the substrate 100 is a color film substrate.

The display panel 2 further includes:

an array substrate disposed opposite to the color film substrate; and

a liquid crystal layer disposed between the array substrate and the substrate body of the color film substrate.

The display panel 2 of this embodiment is a liquid crystal display panel. The structure of the color film substrate is referred to the structure of the substrate 100 in the above embodiment, namely, the periphery of the substrate body 110 of the color film substrate is provided with the hang buckle connecting member 120. Therefore, the entire display device 1 assembled by the display panel 2 is able to be wall-mounted by fixing the hang buckle connecting member 120 of the color film substrate.

The liquid crystal layer is prepared by mixing a plurality of liquid crystal molecules, and is filled between the color film substrate and the array substrate. As anisotropic crystals, the liquid crystal molecules has an optical anisotropy and therefore has a polarizing function. Under the applied voltage control, the liquid crystal molecules rotate due to the dielectric anisotropy of the liquid crystal, so that the refractive index or transmittance of the liquid crystal also changes correspondingly, thereby controlling the out light. After removing the applied voltage, the liquid crystal returns to the state before the external force is applied by the elastic potential energy.

In an embodiment of the present disclosure, as shown in FIG. 1 and FIG. 2, the substrate 100 is an array substrate.

The display panel 2 further includes:

a color film substrate disposed opposite to the array substrate; and

a liquid crystal layer disposed between the color film substrate and the substrate body 110 of the array substrate.

The display panel 2 of this embodiment is a liquid crystal display panel. The structure of the array substrate is referred to the structure of the substrate 100 in the above embodiment, namely, the periphery of the substrate body 110 of the array substrate is provided with the hang buckle connecting member 120. Therefore, the entire display device 1 assembled by the display panel 2 is able to be wall-mounted by fixing the hang buckle connecting member 120 of the array substrate.

The liquid crystal layer is prepared by mixing a plurality of liquid crystal molecules, and is filled between the color film substrate and the array substrate. As anisotropic crystals, the liquid crystal molecules has an optical anisotropy and therefore has a polarizing function. Under the applied voltage control, the liquid crystal molecules rotate due to the dielectric anisotropy of the liquid crystal, so that the refractive index or transmittance of the liquid crystal also changes correspondingly, thereby controlling the out light. After removing the applied voltage, the liquid crystal returns to the state before the external force is applied by the elastic potential energy.

In an embodiment of the present disclosure, the display panel 2 includes:

a color film substrate, and the color film substrate is the substrate 100 of any of the above embodiments;

an array substrate, and the array substrate is the substrate 100 of any of the above embodiments; and

a liquid crystal layer, the liquid crystal layer is disposed between the substrate body of the color film substrate and the substrate body of the array substrate.

The display panel 2 of the present embodiment is a liquid crystal display panel. The structure of the color film substrate refers to the structure of the substrate 100 of the above embodiment, namely, the color film substrate includes the substrate body 110 and the hang buckle connecting member 120, and the hang buckle connecting member 120 is fixed at the edge of the substrate body 110, and the hang buckle connecting member 120 is provided with the through hole 121; The structure of the array substrate refers to the structure of the substrate 100 of the above embodiment, namely, the array substrate includes the substrate body 110 and the hang buckle connecting member 120, and the hang buckle connecting member 120 is fixed at the edge of the substrate body 110.

Therefore, the entire display device 1 assembled by the display panel 2 of this embodiment is able to be wall-mounted by fixing both the hang buckle connecting member 120 of the array substrate and the hang buckle connecting member 120 of the color film substrate. Both the array substrate and the color film substrate are provided with a hang buckle connecting member, thereby the overall bearing is more stable.

The liquid crystal layer is prepared by mixing a plurality of liquid crystal molecules, and is filled between the color film substrate and the array substrate. As anisotropic crystals, the liquid crystal molecules have an optical anisotropy and therefore has a polarizing function. Under the applied voltage control, the liquid crystal molecules rotate due to the dielectric anisotropy of the liquid crystal, so that the refractive index or transmittance of the liquid crystal also changes correspondingly, thereby controlling the out light. After removing the applied voltage, the liquid crystal returns to the state before the external force is applied by the elastic potential energy.

The present disclosure further provides a display device 1.

Referring to FIG. 2 and FIG. 3, in an embodiment of the present disclosure, the display device includes the display panel 2 of any of the above embodiments.

In this embodiment, the specific structure of the display panel 2 is referred to the above embodiment. Since the display panel 2 of the display device 1 of this embodiment adopts the technical solution of the above embodiment, it has at least the effects of the technical solutions of the above embodiments and will not be repeated here.

In an embodiment of the present disclosure, the display device 1 further includes a casing 300, and the display panel 2 is mounted on the casing 300, and the hang buckle connecting member 120 protrudes from the casing 300. In this embodiment, the casing 300 acts to protect the display panel 2. Since the hang buckle connecting member 120 protrudes from the casing 300, the display device 1 is able to be hanged to the hang buckle 400 on the wall through the hang buckle connecting member 120, without extra wall-mounted brackets being provided between the casing 300 and the wall, so that the casing 300 is closely attached to the wall.

When the display panel 2 is the OLED display panel, no backlight module of the display device 1 is needed; When the display panel 2 is the liquid crystal display panel, a backlight module is needed to be installed in the display device 1 to provide the light source required for the display panel display.

The above descriptions are only alternative embodiments of the present disclosure, and is not intended to limit the scope of the disclosure of the present disclosure. All the equivalent structural transformation made by the disclosure specification and the attached drawings under the idea of the disclosure, or directly/indirectly used in other relevant technical fields are included in the patent protection scope of the disclosure.

What is claimed is:

1. A substrate, comprising:
a substrate body; and
a hang buckle connecting member fixed at an edge of the substrate body and provided with a through hole.

2. The substrate of claim 1, wherein, the hang buckle connecting member is fixed at a top and/or a lateral side of the substrate body.

3. The substrate of claim 1, wherein, the hang buckle connecting member has a rectangular shape.

4. The substrate of claim 1, wherein, the hang buckle connecting member has a rectangular shape, and the through hole is a rectangular hole.

5. The substrate of claim 1, wherein, the hang buckle connecting member is integrally formed with the substrate body.

6. The substrate of claim 1, wherein, the substrate is a color film substrate or an array substrate.

7. A display panel, wherein, the display panel comprises a substrate;
the substrate comprises:
a substrate body; and
a hang buckle connecting member fixed at an edge of the substrate body and provided with a through hole.

8. The display panel of claim 7, wherein, the hang buckle connecting member is fixed at a top and/or a lateral side of the substrate body.

9. The display panel of claim 7, wherein, the hang buckle connecting member has a rectangular shape.

10. The display panel of claim 7, wherein, the hang buckle connecting member has a rectangular shape, and the through hole is a rectangular hole.

11. The display panel of claim 7, wherein, the hang buckle connecting member is integrally formed with the substrate body.

12. The display panel of claim 7, wherein, the substrate is a color film substrate or an array substrate.

13. The display panel of claim 7, wherein, the substrate is a color film substrate;
the display panel further comprises:
an array substrate disposed opposite to the color film substrate; and
a liquid crystal layer disposed between the array substrate and the substrate body of the color film substrate.

14. The display panel of claim 7, wherein, the substrate is an array substrate;
the display panel further comprises:
a color film substrate disposed opposite to the array substrate; and
a liquid crystal layer disposed between the color film substrate and the substrate body of the array substrate.

15. A display device, wherein, the display device comprises a display panel;
the display panel comprises a substrate;
the substrate comprises:
a substrate body; and
a hang buckle connecting member fixed at an edge of the substrate body and provided with a through hole.

16. The display device of claim 15, wherein, the hang buckle connecting member is fixed at a top and/or a lateral side of the substrate body.

17. The display device of claim 15, wherein, the hang buckle connecting member has a rectangular shape.

18. The display device of claim 15, wherein, the hang buckle connecting member has a rectangular shape, and the through hole is a rectangular hole.

19. The display device of claim 15, wherein, the hang buckle connecting member is integrally formed with the substrate body.

20. The display device of claim 15, wherein, the display device further comprises a casing, the display panel being mounted on the casing, the hang buckle connecting member protruding from the casing.
